(19) United States
(12) Patent Application Publication
(10) Pub. No.: US 2012/0044760 A1
(43) Pub. Date: Feb. 23, 2012

(54) NONVOLATILE SEMICONDUCTOR MEMORY DEVICE AND DRIVING METHOD THEREOF

(76) Inventor: Keita TAKAHASHI, Nara (JP)

(21) Appl. No.: 13/169,803

(22) Filed: Jun. 27, 2011

(30) Foreign Application Priority Data
Aug. 23, 2010 (JP) 2010-186100

(51) Int. Cl. G11C 11/34; H01L 29/792

(52) U.S. Cl. 365/184; 257/324; 257/E29.309

(57) ABSTRACT

A nonvolatile semiconductor memory device has a first select transistor having a gate electrode connected to a first select word line, a source connected to a first sub bit line, and a drain connected to a first main bit line, and a second select transistor having a gate electrode connected to a second select word line, a source connected to a second sub bit line, and a drain connected to a second main bit line. The first sub bit lines are controlled by the first select transistor so as to be electrically isolated from each other between memory cell groups each formed by the memory cells to be erased simultaneously. On the other hand, the second sub bit lines are connected in common to the memory cells of memory cell groups to be erased separately, by the second select transistor.

### CROSS-REFERENCE TO RELATED APPLICATION

This application claims priority to Japanese Patent Application No. 2010-186100 filed on Aug. 23, 2010, the disclosure of which including the specification, the drawings, and the claims is hereby incorporated by reference in its entirety.

### BACKGROUND

The present invention relates to nonvolatile semiconductor memory devices, and more particularly to nonvolatile semiconductor memory devices such as metal oxide-nitride-oxide semiconductor (MONOS) memory devices, and driving methods thereof.

With recent increased integration density and reduced cost of nonvolatile semiconductor memory devices, local trap type MONOS memory devices have been proposed which have a virtual ground array and locally trap charge in an oxide-nitride-oxide (ONO) film as a gate insulating film. The use of the local trap type MONOS memory devices can effectively reduce the memory cell size as they can accumulate charge independently on both drain and source sides of each memory cell and thus can store and retain 2 bits per cell.

A conventional nonvolatile semiconductor memory device will be described below with reference to the accompanying drawings (see, e.g., U.S. Pat. No. 5,963,465).

First, wiring of a memory cell array in the conventional nonvolatile semiconductor memory device will be described below with reference to FIG. 8.

As shown in FIG. 8, a plurality of memory cells 101 are arranged in a matrix pattern (rows and columns). The source and drain of each memory cell 101 are respectively connected to the sources of corresponding ones of select transistors 103 as high breakdown voltage transistors via corresponding ones of sub bit lines 102 extending in an X direction (a row direction). The drain of each select transistor 103 is connected to a corresponding one of main bit lines 104 extending in the X direction, and the gate of each select transistor 103 is connected to a corresponding one of select word lines 106 extending in a Y direction (a column direction). A gate electrode of each memory cell 101 is connected to a corresponding one of memory word lines 105 extending in the Y direction.

Note that as shown by, e.g., a first rewrite sector A and a second rewrite sector B, a rewrite unit of retained data is a group of memory cells 101 that are included in a region interposed between the select transistors 103 and that are in a range that is rewritten by a series of rewrite operations.

In the following description, the “drain” of each memory cell 101 refers to a terminal that serves as a drain when writing a first bit of the memory cell. Similarly, the “source” of each memory cell 101 refers to a terminal that serves as a source when writing the first bit of the memory cell. That is, although the function of each terminal is actually reversed depending on the bit to be written (i.e., each terminal actually serves either as a physical drain or a physical source depending on the bit to be written), the drain and the source are herein fixed as described above for convenience of description.

A method of writing data in a first bit of a cell to be written will be described below with reference to FIG. 9.

As shown in FIG. 9, the cell to be written is the first bit of the circled memory cell 101 connected to WL1 of the memory word lines 105. A voltage of 10 V is applied to WL1, a voltage of 10 V is applied to SWL1 and SWL2 of the select word lines 106, a voltage of 5 V is applied to MBL1 of the main bit lines 104, and a voltage of 0 V is applied to the remaining terminals. Thus, the voltage of 10 V is applied to the gate of the designated memory cell 101, the voltage of 5 V is applied to the drain thereof, and the voltage of 0 V is applied to the source thereof. As a result, channel hot electrons are generated at the drain end, and the electrons are trapped at the drain end of the ONO film of the memory cell 101. Thus, the threshold voltage of the first bit of the memory cell 101 increases from about 2 V in an erased state to about 6 V in a written state.

A method of writing data in a second bit of a cell to be written will be described below with reference to FIG. 10.

As shown in FIG. 10, the cell to be written is the second bit of the circled memory cell 101 connected to WL1 of the memory word lines 105. A voltage of 10 V is applied to WL1, a voltage of 10 V is applied to SWL1 and SWL2 of the select word lines 106, a voltage of 5 V is applied to MBL2 of the main bit lines 104, and a voltage of 0 V is applied to the remaining terminals. Thus, the voltage of 10 V is applied to the gate of the designated memory cell 101, the voltage of 5 V is applied to the source thereof, and the voltage of 0 V is applied to the drain thereof. As a result, channel hot electrons are generated at the source end, and the electrons are trapped at the source end of the ONO film of the memory cell 101. Thus, the threshold voltage of the second bit of the memory cell 101 increases from about 2 V in the erased state to about 6 V in the written state.

By performing the above procedures, data is written to the memory cells 101 included in the first rewrite sector A that is interposed between the select transistors 103 respectively connected to the upstream and downstream sides of the main bit lines 104. The sub bit lines 102 connected to the memory cells 101 included in the first rewrite sector A are electrically isolated from the second rewrite sector B by the two select transistors 103. Thus, in the write operation, the voltage of 5 V that is applied to the drain or source of the memory cell 101 to be rewritten is not applied to the sub bit lines 102 in the second rewrite sector B. Accordingly, the state of each memory cell 101 included in the second rewrite sector B does not change when writing the memory cells 101 in the first rewrite sector A. That is, it is ensured that the memory cells 101 in the second rewrite sector B do not change from the erased state to the written state or from the written state to the erased state.

A method of erasing data of the first bits of cells to be erased will be described below with reference to FIG. 11.

As shown in FIG. 11, the memory cells 101 to be erased are the first bits of the circled memory cells 101 connected to WL0 to WL2 of the memory word lines 105. A voltage of −5 V is applied to WL0 to WL2, a voltage of 10 V is applied to SWL0 and SWL1 of the select word lines 106, a voltage of 5 V is applied to MBL1 and MBL3 of the main bit lines 104, and a voltage of 0 V is applied to the remaining terminals. Thus, the voltage of −5 V is applied to the gates of the memory cells 101 included in the first rewrite sector A, the voltage of 5 V is applied to the drains thereof, and the sources thereof are in an open state. As a result, a band-to-band tunneling current is generated at the drain end of each memory cell 101, and holes are trapped at the drain end of the ONO film of each memory cell 101. Accordingly, the threshold voltage of the first bit of each memory cell 101 decreases from about 6 V in the written state to about 2 V in the erased state.

A method of erasing data of the second bits of cells to be erased will be described below with reference to FIG. 12.

As shown in FIG. 12, the memory cells 101 to be erased are the second bits of the circled memory cells 101 connected to WL0 to WL2 of the memory word lines 105. A voltage of −5 V is applied to WL0 to WL2, a voltage of 10 V is applied to SWL2 and SWL3 of the select word lines 106, a voltage of 5 V is applied to MBL0, MBL2, and MBL4 of the main bit lines 104, and a voltage of 0 V is applied to the remaining terminals. Thus, the voltage of −5 V is applied to the gates of the memory cells 101 included in the first rewrite sector A, the voltage of 5 V is applied to the sources thereof, and the drains thereof are in an open state. As a result, a band-to-band tunneling current is generated at the source end of each memory cell 101, and holes are trapped at the source end of the ONO film of each memory cell 101. Thus, the threshold voltage of the second bit of each memory cell 101 decreases from about 6 V in the written state to about 2 V in the erased state.

By performing the above procedures, retained data is erased from the memory cells 101 included in the first rewrite sector A that is interposed between the select transistors 103 respectively connected to the upstream and downstream sides of the main bit lines 104. The sub bit lines 102 connected to the memory cells 101 included in the first rewrite sector A are electrically isolated from the second rewrite sector B by the select transistors 103. Thus, in the erase operation, the voltage of 5 V that is applied to the drains or sources of the memory cells 101 to be erased is not applied to the sub bit lines 102 in the second rewrite sector B. Accordingly, it is ensured that the state of each memory cell 101 included in the second rewrite sector B does not change when erasing the memory cells 101 in the first rewrite sector A.

A method of reading data of the first bit of a cell to be read will be described below with reference to FIG. 13.

As shown in FIG. 13, the memory cell 101 to be read is the first bit of the circled memory cell 101 connected to WL1 of the memory word lines 105. A voltage of 5 V is applied to WL1, a voltage of 5 V is applied to SWL1 and SWL2 of the select word lines 106, a voltage of 1 V is applied to MBL2 of the main bit lines 104, and a voltage of 0 V is applied to the remaining terminals. Thus, the voltage of 5 V is applied to the gate of the designated memory cell 101, the voltage of 1 V is applied to the source thereof, and the voltage of 0 V is applied to the drain thereof, whereby a channel current flows from the source to the drain.

The channel current that flows in the read operation is about 20 μA in the erased state (the threshold voltage is about 2 V) where holes are trapped at the drain end of the ONO film, but is less than 1 μA in the written state (the threshold voltage is about 6 V) where electrons are trapped at the drain end of the ONO film. Thus, the retained data can be determined by the channel current.

A method of reading data of the second bit of a cell to be read will be described below with reference to FIG. 14.

As shown in FIG. 14, the memory cell 101 to be read is the second bit of the circled memory cell 101 connected to WL1 of the memory word lines 105. A voltage of 5 V is applied to WL1, a voltage of 5 V is applied to SWL1 and SWL2 of the select word lines 106, a voltage of 1 V is applied to MBL1 of the main bit lines 104, and a voltage of 0 V is applied to the remaining terminals. Thus, the voltage of 5 V is applied to the gate of the designated memory cell 101, the voltage of 0 V is applied to the source thereof, and the voltage of 1 V is applied to the drain thereof, whereby a channel current flows from the drain to the source.

By performing the above procedures, data is read from the memory cells 101 included in the first rewrite sector A that is interposed between the select transistors 103 respectively connected to the upstream and downstream sides of the main bit lines 104. The sub bit lines 102 connected to the memory cells 101 included in the first rewrite sector A are electrically isolated from the second rewrite sector B by the two select transistors 103. Thus, in the read operation, the voltage of 1 V that is applied to the drain or source of the memory cell 101 to be read is not applied to the sub bit lines 102 in the second rewrite sector B. Accordingly, it is ensured that the state of each memory cell 101 included in the second rewrite sector B does not change when reading the memory cells 101 in the first rewrite sector A.

### SUMMARY

However, since the conventional nonvolatile semiconductor memory device retains 2-bit data per cell, phenomena occur such as a phenomenon (2^{nd} Bit Effect) in which the threshold voltage of the second bit appears to increase due to electrons written in the first bit, and a phenomenon (a soft program) in which the second bit is gradually written if the first bit is continuously read, thereby causing a reliability problem. Thus, the conventional nonvolatile semiconductor memory device is reliable enough as a general-purpose memory device, but is not reliable enough for applications of nonvolatile memory devices that are mounted on microcomputers, namely microcomputer-mounted memory applications. The general-purpose memory devices need only be designed on the assumption that the read time of a certain bit is “10 years/the total number of bits/the number of bits that are read simultaneously,” while the microcomputers are designed on the assumption that the microcomputers may be used under the condition that the same bit is continuously read for 10 years. Thus, the conventional nonvolatile semiconductor memory device is not reliable enough in terms of the soft program. Another factor that affects the reliability of the conventional nonvolatile semiconductor memory device in the microcomputer-mounted applications is the read speed (access time of 20 ns, etc.) that is about twice that in the general-purpose memory devices.

One possible method to increase the reliability while making use of the features of local trap type memory cells having a small area is to limit the microcomputer-mounted memory applications to the specification in which 1-bit data is retained per cell.

However, applying this method to the conventional memory cell array results in a waste of the area in the configuration of the select transistors, because the related art is designed based on the specification in which 2-bit data is retained per cell. That is, the occupied area is increased by the plurality of select transistors, whereby efficiency of memory cell layout is reduced.

In view of the above problems, it is an object of the present invention to reduce the area occupied by select transistors so that the efficiency of cell layout can be increased.

In order to achieve the above object, a nonvolatile semiconductor memory device according to the present invention is configured so that select transistors provided in each rewrite sector are arranged separately as the select transistor for a rewrite operation and the select transistor for a read operation, and the select transistor for the read operation is shared by the plurality of rewrite sectors.

Specifically, a nonvolatile semiconductor memory device according to the present invention is a nonvolatile semiconductor memory device including: a semiconductor region; a plurality of charge trapping memory cells formed on the semiconductor region and arranged in rows and columns, and each having a first electrode, a second electrode, and a third electrode; a plurality of word lines each connecting in common the first electrodes of the plurality of memory cells arranged in a column direction; a plurality of first sub bit lines each connecting in common the second electrodes of the plurality of memory cells arranged in a row direction; a plurality of second sub bit lines each connecting in common the third electrodes of the plurality of memory cells arranged in the row direction; a first select transistor having a gate electrode connected to a first select word line extending in the column direction, a source connected to the first sub bit line, and a drain connected to a first main bit line extending in the row direction; and a second select transistor having a gate electrode connected to a second select word line extending in the column direction, a source connected to the second sub bit line, and a drain connected to a second main bit line extending in the row direction, wherein each of the memory cells is capable of retaining 1-bit data, the first sub bit lines are controlled by the first select transistor so as to be electrically isolated from each other between memory cell groups each formed by the memory cells to be erased simultaneously, and the second sub bit lines are connected in common to the memory cells of memory cell groups (e.g., rewrite sectors) to be erased separately, by the second select transistor.

According to the nonvolatile semiconductor memory device of the present invention, since the second sub bit lines are connected in common to the memory cells of the memory cell groups to be erased separately, by the second select transistor. Accordingly, the number of second select transistors can be reduced, whereby the overall area occupied by the select transistors can be reduced, and thus the efficiency of cell layout can be increased.

In the nonvolatile semiconductor memory device of the present invention, in each of the memory cells, the first electrode may be a gate electrode, the second electrode and the third electrode may be respectively formed by diffusion layers formed in the semiconductor region, the second electrode may function as a drain in a write operation to the memory cell, and the third electrode may function as a drain in a read operation from the memory cell.

In the nonvolatile semiconductor memory device of the present invention, the plurality of memory cells may be formed by at least two rewrite sectors, and the second select transistor may be placed in a boundary region between adjoining two of the rewrite sectors.

In the nonvolatile semiconductor memory device of the present invention, each of the memory cells may have a gate insulating film between the semiconductor region and the first electrode, and the gate insulating film may be formed by stacking at least a silicon oxide film and a silicon nitride film, and may be capable of trapping carriers.

A method for driving the nonvolatile semiconductor memory device of the present invention includes: applying a first voltage only to the first sub bit line when writing and erasing the memory cell; and applying a second voltage only to the second sub bit line when reading the memory cell, wherein the first voltage is higher than the second voltage.

In the method for driving the nonvolatile semiconductor memory device of the present invention, the first voltage may be 5 V, and the second voltage may be 1 V.

Thus, according to the nonvolatile semiconductor memory device of the present invention, the select transistor for the read operation, for example, can be shared by the plurality of rewrite sectors, whereby the overall area of the select transistors can be reduced. Thus, the efficiency of cell layout in the nonvolatile semiconductor memory device can be increased.

### BRIEF DESCRIPTION OF THE DRAWINGS

FIG. 1 is a partial circuit diagram showing a memory cell array of a nonvolatile semiconductor memory device according to an example embodiment.

FIG. 2 is a partial circuit diagram illustrating a first write method in the nonvolatile semiconductor memory device according to the example embodiment.

FIG. 3 is a partial circuit diagram illustrating a second write method in the nonvolatile semiconductor memory device according to the example embodiment.

FIG. 4 is a partial circuit diagram illustrating a first erase method in the nonvolatile semiconductor memory device according to the example embodiment.

FIG. 5 is a partial circuit diagram illustrating a second erase method in the nonvolatile semiconductor memory device according to the example embodiment.

FIG. 6 is a partial circuit diagram illustrating a first read method in the nonvolatile semiconductor memory device according to the example embodiment.

FIG. 7 is a partial circuit diagram illustrating a second read method in the nonvolatile semiconductor memory device according to the example embodiment.

FIG. 8 is a partial circuit diagram showing a memory cell array of a conventional nonvolatile semiconductor memory device.

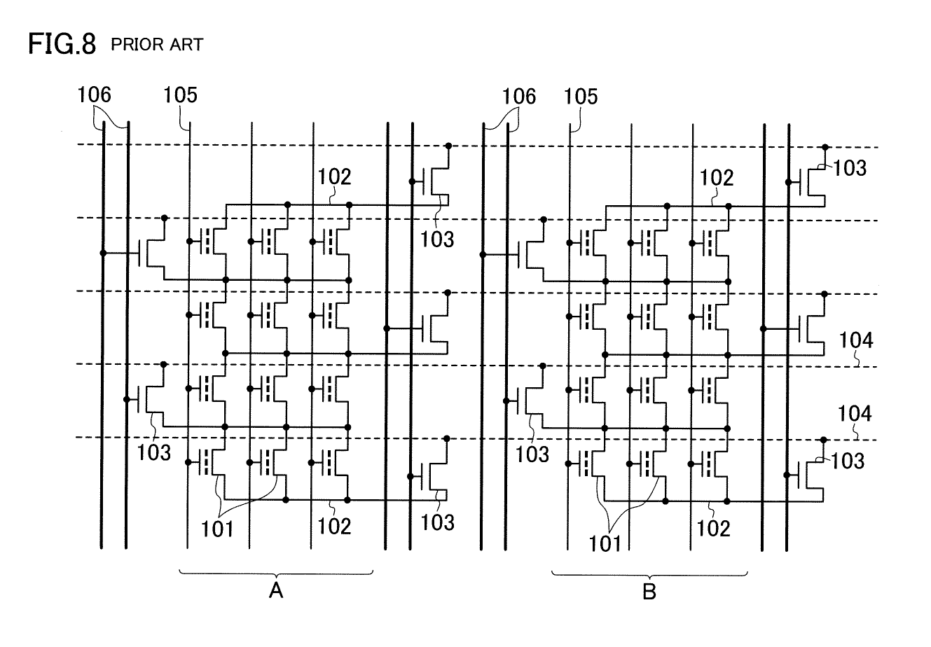

FIG. 9 is a partial circuit diagram illustrating a first write method in the conventional nonvolatile semiconductor memory device.

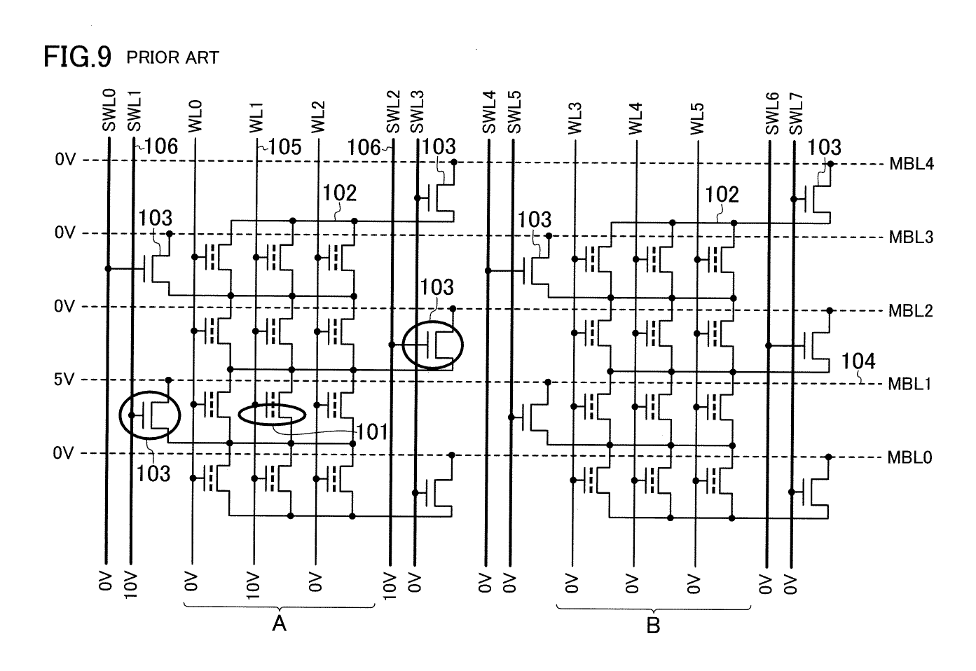

FIG. 10 is a partial circuit diagram illustrating a second write method in the conventional nonvolatile semiconductor memory device.

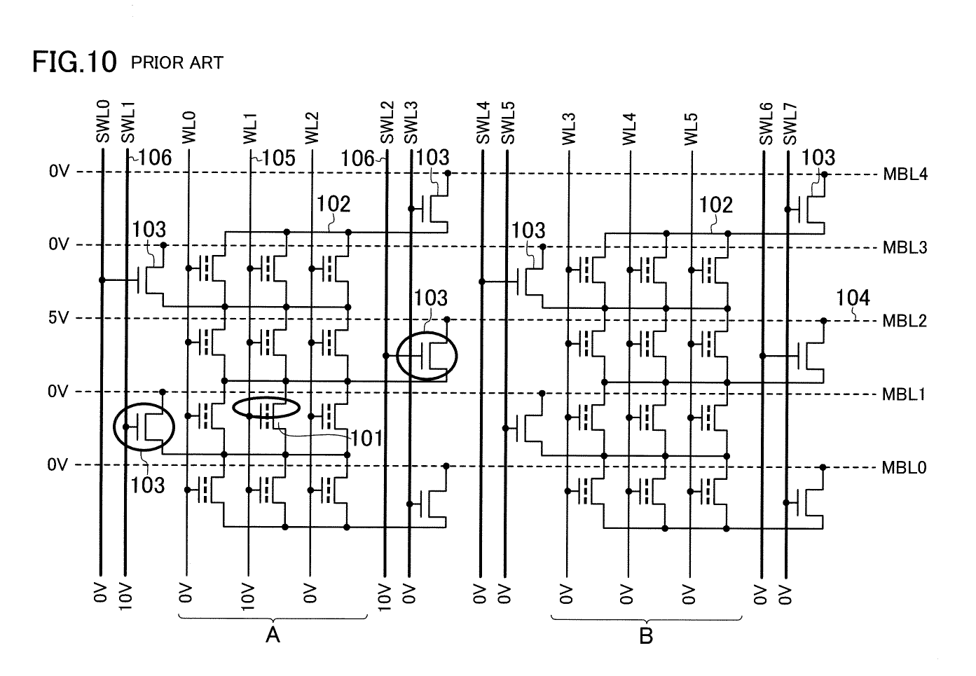

FIG. 11 is a partial circuit diagram illustrating a first erase method in the conventional nonvolatile semiconductor memory device.

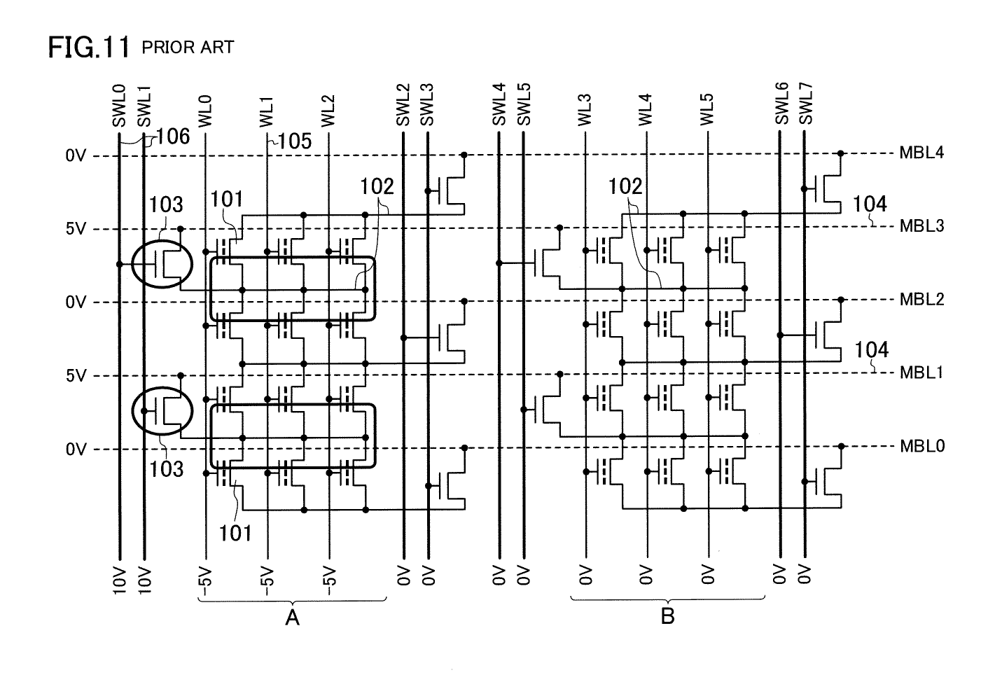

FIG. 12 is a partial circuit diagram illustrating a second erase method in the conventional nonvolatile semiconductor memory device.

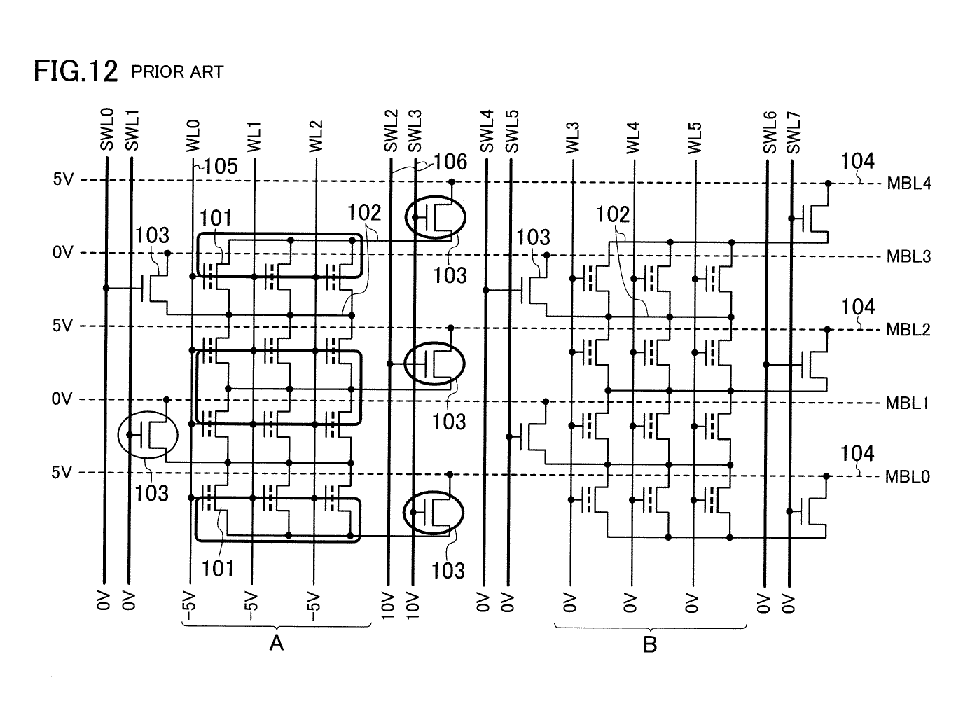

FIG. 13 is a partial circuit diagram illustrating a first read method in the conventional nonvolatile semiconductor memory device.

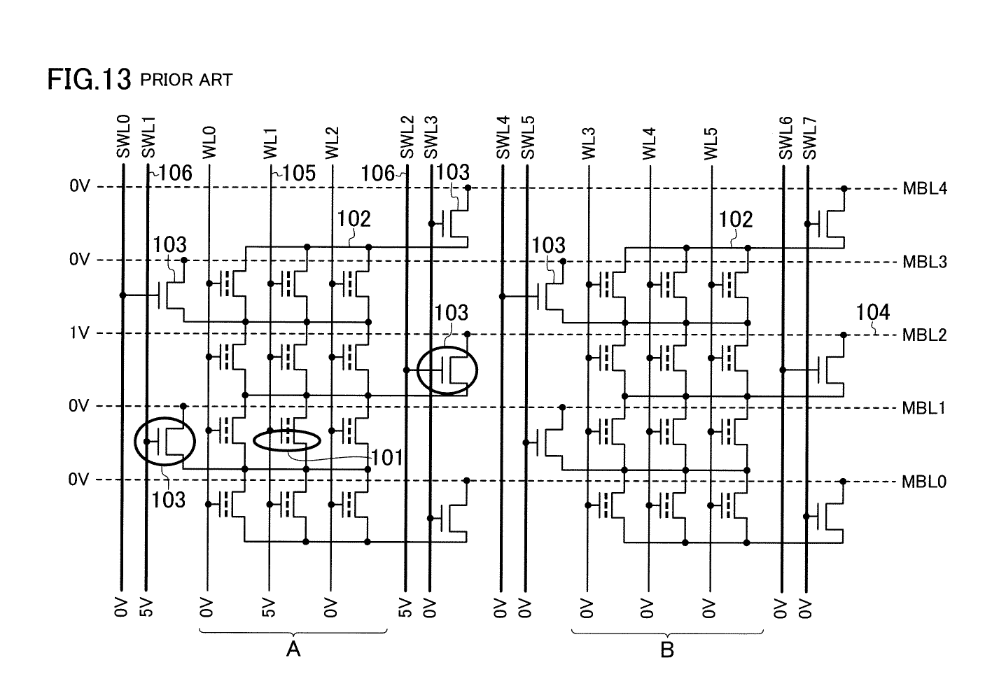

FIG. 14 is a partial circuit diagram illustrating a second read method in the conventional nonvolatile semiconductor memory device.

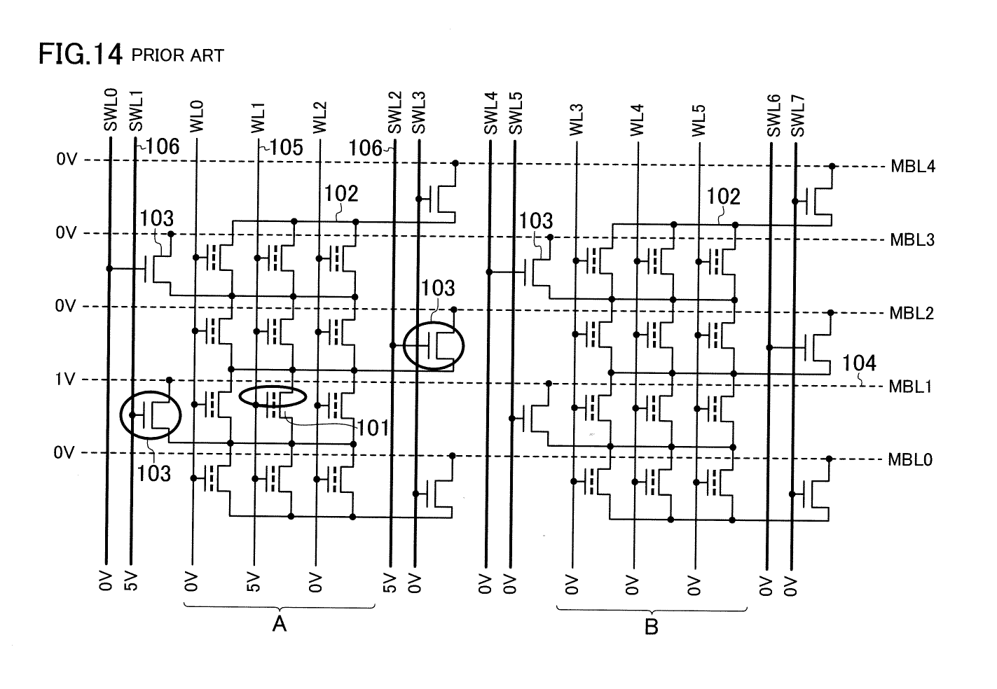

### DETAILED DESCRIPTION

### Example Embodiment

A nonvolatile semiconductor memory device according to an example embodiment will be described below with reference to the accompanying drawings.

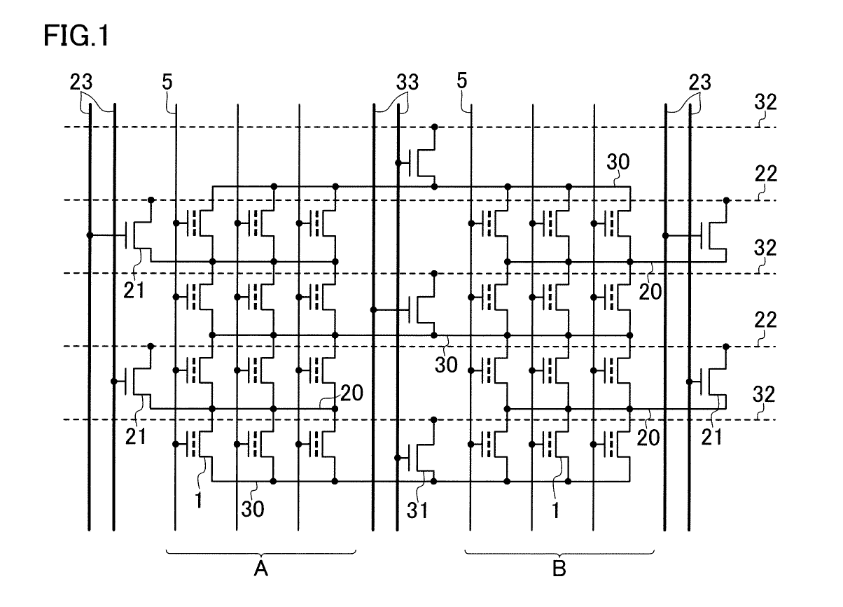

First, wiring of a memory cell array of the nonvolatile semiconductor memory device according to the example embodiment will be described below with reference to FIG. 1.

As shown in FIG. 1, the nonvolatile semiconductor memory device of the example embodiment has a semiconductor region formed by a semiconductor substrate (not shown), etc., and a plurality of memory cells 1 formed on the semiconductor region and arranged in, e.g., a matrix pattern (rows and columns). The drain of each memory cell 1 is connected to the source of a corresponding one of first select transistors 21 via a corresponding one of first sub bit lines 20 extending in an X direction (a row direction). The drain of each first select transistor 21 is connected to a corresponding one of first main bit lines 22 extending in the X direction, and the gate of each first select transistor 21 is connected to a corresponding one of first select word lines 23 extending in a Y direction (a column direction). The source of each memory cell 1 is connected to the source of a corresponding one of second select transistors 31 via a corresponding one of second sub bit lines 30 extending in the X direction. The gate of each memory cell 1 is connected to a corresponding one of memory word lines (word lines) 5. For example, although not shown in the figure, a gate insulating film having an ONO film structure in which a silicon nitride (SiN) film is vertically interposed between silicon oxide (SiO₂) films is used as a charge trapping film that is provided between the gate of each memory cell 1 or the memory word line 5 and the semiconductor region. Note that the trapping film is not limited to the ONO film, and may have any structure in which at least one layer of the SiN film is interposed between insulating films. An insulating film containing fine conductor particles having a particle size of about several nanometers, such as silicon (Si) particles, may be used instead of the SiN film.

The drain of each second select transistor 31 is connected to a corresponding one of second main bit lines 32 extending in the X direction, and the gate of each second select transistor 31 is connected to a corresponding one of second select word lines 33 extending in the Y direction. A gate electrode of each memory cell 1 is connected to a corresponding one of the memory word lines 5 extending in the Y direction. For example, high breakdown voltage transistors having a gate oxide film with a thickness of about 20 nm, and having a gate length of about 0.7 μm are used as the first select transistors 21 and the second select transistors 31 so that the first and second select transistors 21, 31 can be driven at a voltage of up to about 10 V that is applied in a write operation.

Note that the drain and source of each memory cell 1 are formed by diffusion layers formed in the semiconductor region, and one of the diffusion layers functions as a drain in a write operation, and the other diffusion layer functions as a drain in a read operation. The drain and source of each select transistor 21, 31 are also formed by diffusion layers formed in the semiconductor region.

As shown by, e.g., a first rewrite sector A and a second rewrite sector B, as a rewrite unit of stored (retained) data in the plurality of memory cells 1, a group of memory cells 1 that are connected to the first sub bit line 20 are rewritten at a time.

Thus, a feature of the example embodiment is that the second sub bit lines 30 that are driven by the second select transistors 31 are shared between the first rewrite sector A and the second rewrite sector B.

(Write Method)

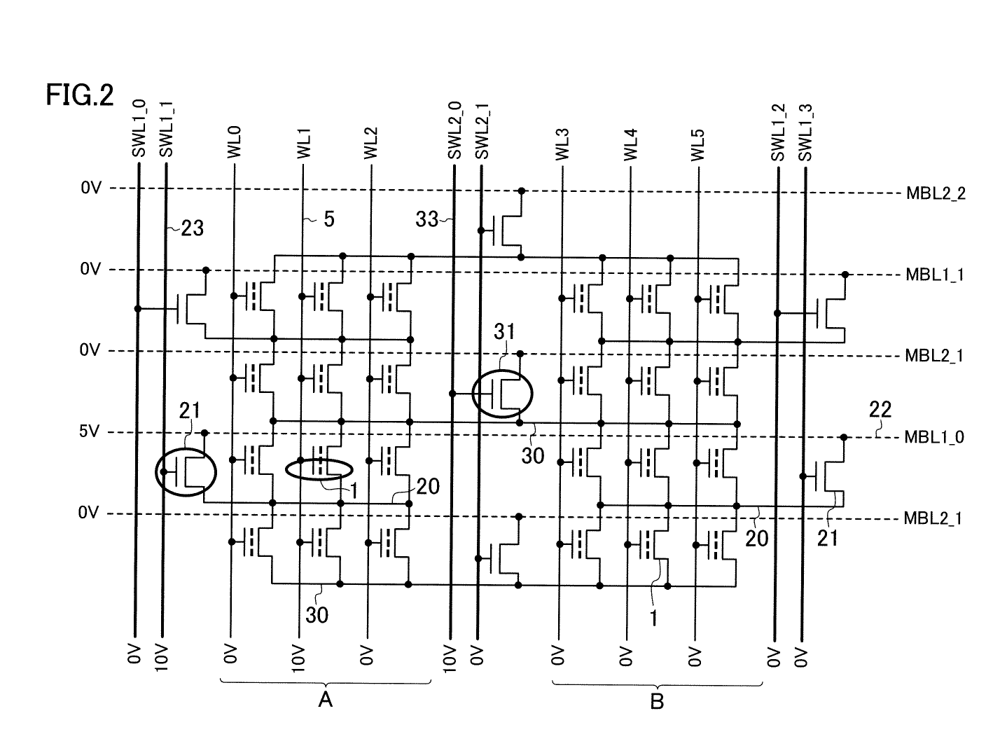

A method of writing data to a cell to be written in the first rewrite sector A will be described below with reference to FIG. 2.

As shown in FIG. 2, the cell to be written is the circled memory cell 1 that is connected to WL1 of the memory word lines 5. A voltage of 10 V is applied to WL1, a voltage of 10 V is applied to SWL1_1 of the first select word lines 23, a voltage of 10 V is applied to SWL2_0 of the second select word lines 33, a voltage of 5 V is applied to MBL1_0 of the first main bit lines 22, and a voltage of 0 V is applied to the remaining terminals. Thus, the voltage of 10 V is applied to the gate of the designated memory cell 1, the voltage of 5 V is applied to the drain thereof, and the voltage of 0 V is applied to the source thereof. Accordingly, channel hot electrons are generated at the drain end of the memory cell 1, and the electrons are trapped at the drain end of the ONO film of the memory cell 1. As a result, the threshold voltage of the memory cell 1 increases from about 2 V in an erased state to about 6 V in a written state.

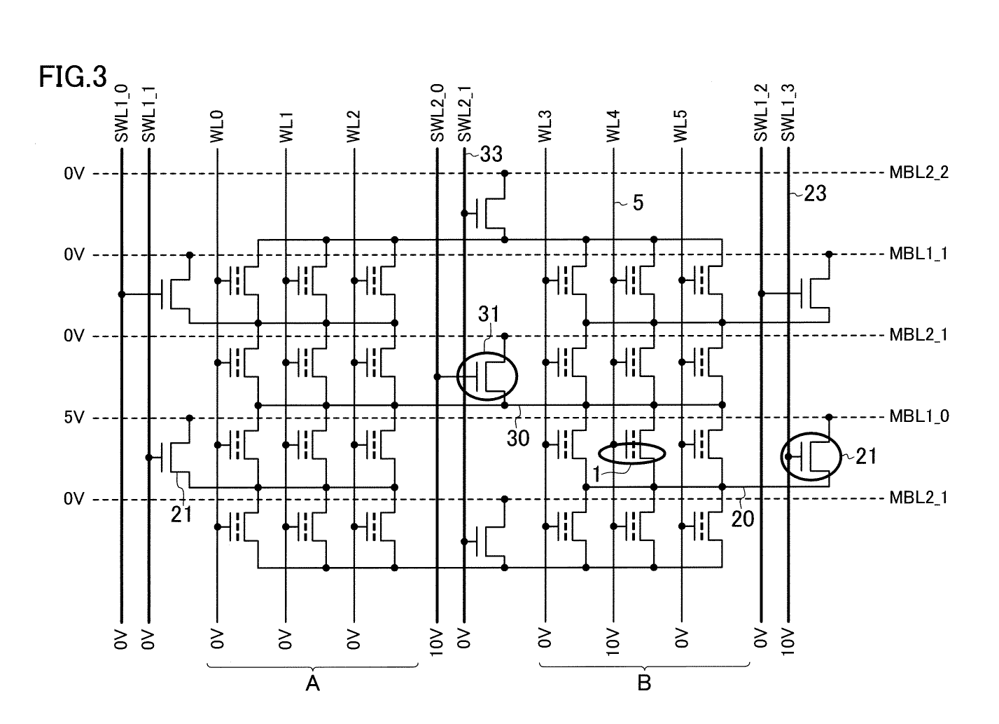

FIG. 3 shows by way of example a method of writing data to a cell to be written in the second rewrite sector B. As shown in FIG. 3, the cell to be written is the circled memory cell 1 that is connected to WL4 of the memory word lines 5. A voltage of 10 V is applied to WL4, a voltage of 10 V is applied to SWL1_3 of the first select word lines 23, a voltage of 10 V is applied to SWL2_0 of the second select word lines 33, a voltage of 5 V is applied to MBL1_0 of the first main bit lines 22, and a voltage of 0 V is applied to the remaining terminals. Thus, the voltage of 10 V is applied to the gate of the designated memory cell 1, the voltage of 5 V is applied to the drain thereof, and the voltage of 0 V is applied to the source thereof. Accordingly, channel hot electrons are generated at the drain end of the memory cell 1, and the electrons are trapped at the drain end of the ONO film of the memory cell 1. As a result, the threshold voltage of the memory cell 1 increases from about 2 V in the erased state to about 6 V in the written state.

Thus, a feature of the example embodiment is to write data of only 1 bit of each memory cell 1 having its drain on the side of the first sub bit line 20 that is driven by the first select transistor 21.

By performing the above procedures, data is written to the memory cells 1 included in the first rewrite sector A and the second rewrite sector B. The first sub bit lines 20 connected to the memory cells 1 included in the first rewrite sector A are electrically isolated from the second rewrite sector B by the first select transistors 21. Thus, in the write operation, the voltage of 5 V, which is applied to the first sub bit line 20 connected to the memory cells 1 to be rewritten in the first rewrite sector A, is not applied to the first sub bit lines 20 in the second rewrite sector B. Accordingly, the state of each memory cell 1 included in the second rewrite sector B does not change when writing the memory cells 1 in the first rewrite sector A. That is, it is ensured that each memory cell 1 in the second rewrite sector B does not change from the erased state to the written state.

(Erase Method)

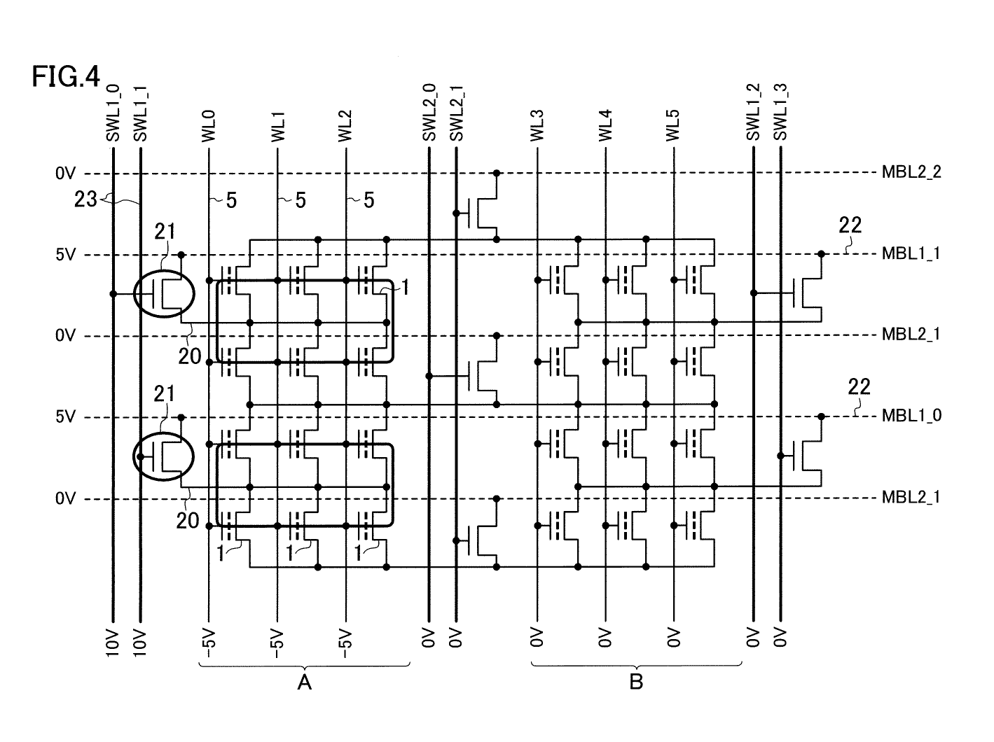

A method of erasing data from the memory cells 1 in the first rewrite sector A will be described below with reference to FIG. 4.

As shown in FIG. 4, the cells to be erased are the circled memory cells 1 connected to WL0 to WL2 of the memory word lines 5. A voltage of −5 V is applied to WL0 to WL2, a voltage of 10 V is applied to SWL1_0 and SWL1_1 of the first select word lines 23, a voltage of 5 V is applied to MBL1_0 and MBL1_1 of the first main bit lines 22, and a voltage of 0 V is applied to the remaining terminals. Thus, the voltage of −5 V is applied to the gates of the memory cells 1, the voltage of 5 V is applied to the drains thereof, and the sources thereof are in an open state. As a result, a band-to-band tunneling current is generated at the drain end of each memory cell 1, and holes are trapped at the drain end of the ONO film of each memory cell 1. Thus, the threshold voltage of each memory cell 1 decreases from about 6 V in the written state to about 2 V in the erased state.

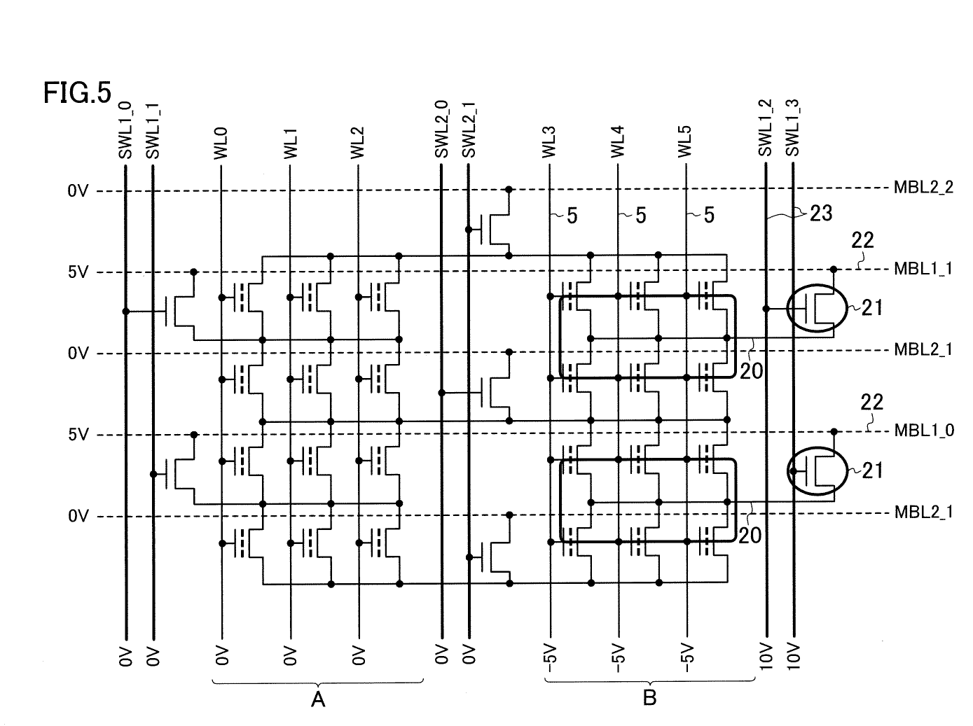

FIG. 5 shows by way of example a method of erasing data from the memory cells 1 in the second rewrite sector B.

As shown in FIG. 5, the cells to be erased are the circled memory cells 1 connected to WL3 to WL5 of the memory word lines 5. A voltage of −5 V is applied to WL3 to WL5, a voltage of 10 V is applied to SWL1_2 and SWL1_3 of the first select word lines 23, a voltage of 5 V is applied to MBL1_0 and MBL1_1 of the first main bit lines 22, and a voltage of 0 V is applied to the remaining terminals. Thus, the voltage of −5 V is applied to the gates of the memory cells 1, the voltage of 5 V is applied to the drains thereof, and the sources thereof are in an open state. As a result, a band-to-band tunneling current is generated at the drain end of each memory cell 1, and holes are trapped at the drain end of the ONO film of each memory cell 1. Accordingly, the threshold voltage of each memory cell 1 decreases from about 6 V in the written state to about 2 V in the erased state.

Thus, a feature of the example embodiment is to erase only 1 bit of each memory cell 1 having its drain on the side of the first sub bit line 20 that is driven by the first select transistor 21.

By performing the above procedures, data is erased from each memory cell 1 included in the first rewrite sector A and the second rewrite sector B. The first sub bit lines 20 connected to the memory cells 1 included in the first rewrite sector A are electrically isolated from the second rewrite sector B by the first select transistors 21. Thus, in the erase operation, the voltage of 5 V that is applied to the first sub bit lines 20 connected to the memory cells 1 to be erased is not applied to the first sub bit lines 20 in the second rewrite sector B. Accordingly, the state of each memory cell 1 included in the second rewrite sector B does not change when erasing the memory cells 1 in the first rewrite sector A. That is, it is ensured that each memory cell 1 in the second rewrite sector B does not change from the written state to the erased state.

(Read Method)

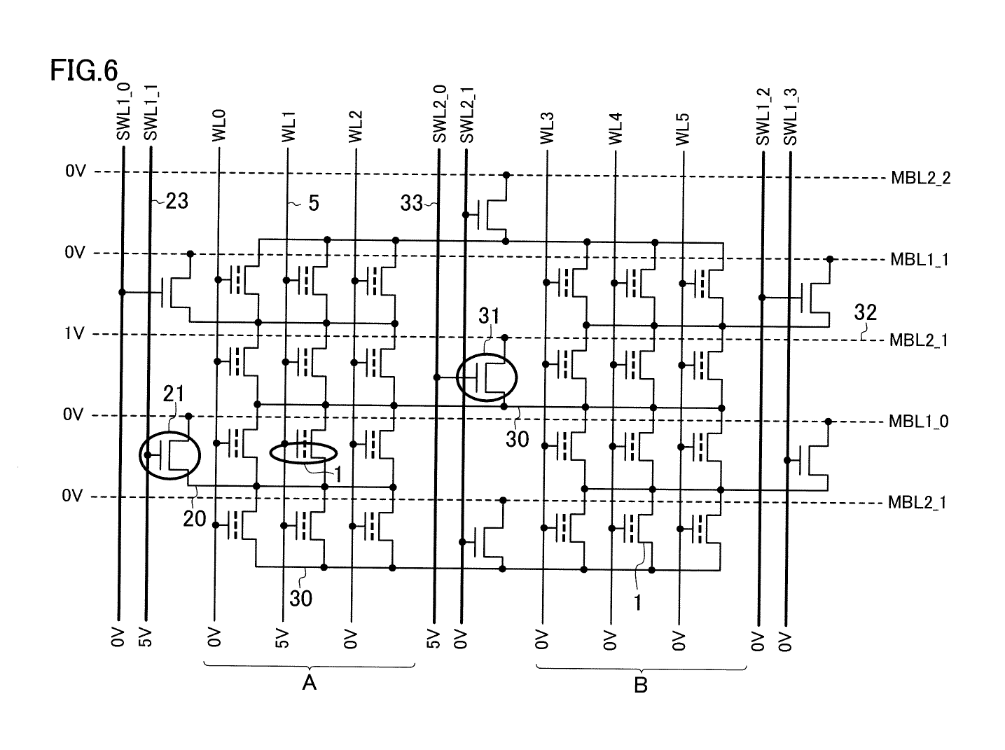

A method of reading data from a cell to be read in the first rewrite sector A will be described below with reference to FIG. 6.

As shown in FIG. 6, the cell to be read is the circled memory cell 1 that is connected to WL1 of the memory word lines 5. A voltage of 5 V is applied to WL1, a voltage of 5 V is applied to SWL1_1 of the first select word lines 23, a voltage of 5 V is applied to SWL2_0 of the second select word lines 33, a voltage of 1 V is applied to MBL2_1 of the second main bit lines 32, and a voltage of 0 V is applied to the remaining terminals. Thus, the voltage of 5 V is applied to the gate of the designated memory cell 1, the voltage of 1 V is applied to the source thereof, and the voltage of 0 V is applied to the drain thereof. As a result, a channel current flows from the source to the drain. Since the channel current that flows in the read operation is about 20 μA in the erased state (the threshold voltage is about 2V), but is less than 1 μA in the written state (the threshold voltage is about 6 V), the retained data can be determined by the channel current.

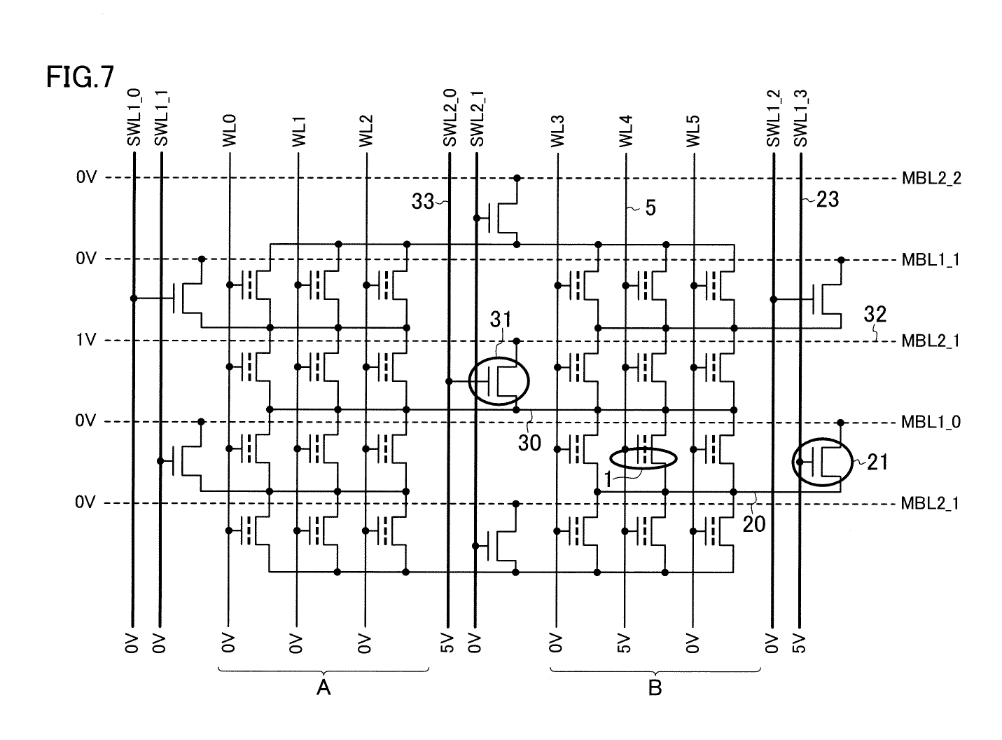

FIG. 7 shows by way of example a method of reading data from a cell to be read in the second rewrite sector B. As shown in FIG. 7, the cell to be read is the circled memory cell 1 that is connected to WL4 of the memory word lines 5. A voltage of 5 V is applied to WL4, a voltage of 5 V is applied to SWL1_3 of the first select word lines 23, a voltage of 5 V is applied to SWL2_0 of the second select word lines 33, a voltage of 1 V is applied to MBL2_1 of the second main bit lines 32, and a voltage of 0 V is applied to the remaining terminals. Thus, the voltage of 5 V is applied to the gate of the designated memory cell 1, the voltage of 1 V is applied to the source thereof, and the voltage of 0 V is applied to the drain thereof. As a result, a channel current flows from the source to the drain. Since the channel current that flows in the read operation is about 20 μA in the erased state (the threshold voltage is about 2V), but is less than 1 μA in the written state (the threshold voltage is about 6 V), the retained data can be determined by the channel current.

Thus, a feature of the example embodiment is to read only those memory cells 1 having their sources connected to the second sub bit line 30 that is driven by the second select transistor 31.

By performing the above procedures, data can be read from the memory cells 1 included in the first rewrite sector A and the second rewrite sector B. The second sub bit line 30 connected to the memory cells 1 included in the first rewrite sector A and the second rewrite sector B is simultaneously driven by the same second select transistor 31. Since the second sub bit line 30 is connected to the sources of the memory cells 1, the state of electrons or holes trapped at the drain end of the ONO film of each memory cell 1 does not change at this time. Accordingly, the state of each memory cell 1 included in the second rewrite sector B does not change when reading data from the memory cells 1 in the first rewrite sector A. That is, it is ensured that each memory cell 1 in the second rewrite sector B does not change from the erased state to the written state or from the written state to the erased state.

As described above, in the example embodiment, the first select transistors 21 and the first sub bit lines 20 are provided in each of the rewrite sectors. On the other hand, the second select transistors 31 and the second sub bit lines 30 are shared by the plurality of rewrite sectors. Since high breakdown voltage transistors having a larger size than the memory cells 1 are used as the select transistors 21, 31, sharing the second select transistors 31 between the first rewrite sector A and the second rewrite sector B significantly reduces the area.

The first select transistors 21 and the first sub bit lines 20 are used when applying a high voltage of about 5 V in the write operation and the erase operation, while the second select transistors 31 and the second sub bit lines 30 are used when applying a low voltage of about 1 V in the read operation. In this manner, separate functions can be assigned to the first select transistors 21 and the first sub bit lines 20, and the second select transistors 31 and the second sub bit lines 30.

Although the second select transistors 31 are shared between the adjoining two rewrite sectors A, B in the present embodiment, the second select transistors 31 may be shared among three or more rewrite sectors. In this case, it is preferable to place the second select transistors 31 in any of the boundary regions between adjoining two of the rewrite sectors.

As described above, according to the present embodiment, some of the select transistors between the rewrite sectors can be shared by the plurality of rewrite sectors, the number of select transistors that occupy a large area can be reduced, whereby the efficiency of cell layout can be increased. The overall area of the select transistors can be reduced specifically by about 10% of the cell array area, although the percentage of the area reduction depends on the array configuration.

Thus, in the nonvolatile semiconductor memory device and the driving method thereof according to the present disclosure, the overall area of the select transistors is reduced, whereby the efficiency of cell layout in the nonvolatile semiconductor memory device can be increased. In particular, the present disclosure is useful for nonvolatile semiconductor memory devices such as a MONOS memory device, driving methods thereof, etc.

What is claimed is:

1. A nonvolatile semiconductor memory device, comprising:
a semiconductor region;
a plurality of charge trapping memory cells formed on the semiconductor region and arranged in rows and columns, and each having a first electrode, a second electrode, and a third electrode;
a plurality of word lines each connecting in common the first electrodes of the plurality of memory cells arranged in a column direction;
a plurality of first sub bit lines each connecting in common the second electrodes of the plurality of memory cells arranged in a row direction;
a plurality of second sub bit lines each connecting in common the third electrodes of the plurality of memory cells arranged in the row direction;
a first select transistor having a gate electrode connected to a first select word line extending in the column direction, a source connected to the first sub bit line, and a drain connected to a first main bit line extending in the row direction; and
a second select transistor having a gate electrode connected to a second select word line extending in the column direction, a source connected to the second sub bit line, and a drain connected to a second main bit line extending in the row direction, wherein
each of the memory cells is capable of retaining 1-bit data,
the first sub bit lines are controlled by the first select transistor so as to be electrically isolated from each other between memory cell groups each formed by the memory cells to be erased simultaneously, and
the second sub bit lines are connected in common to the memory cells of memory cell groups to be erased separately, by the second select transistor.

2. The nonvolatile semiconductor memory device of claim 1, wherein
in each of the memory cells,
the first electrode is a gate electrode,
the second electrode and the third electrode are respectively formed by diffusion layers formed in the semiconductor region,
the second electrode functions as a drain in a write operation to the memory cell, and
the third electrode functions as a drain in a read operation from the memory cell.

3. The nonvolatile semiconductor memory device of claim 1, wherein
the plurality of memory cells are formed by at least two rewrite sectors, and
the second select transistor is placed in a boundary region between adjoining two of the rewrite sectors.

4. The nonvolatile semiconductor memory device of claim 1, wherein
each of the memory cells has a gate insulating film between the semiconductor region and the first electrode, and the gate insulating film is formed by stacking at least a silicon oxide film and a silicon nitride film, and is capable of trapping carriers.

5. A method for driving the nonvolatile semiconductor memory device of claim 1, comprising:
applying a first voltage only to the first sub bit line when writing and erasing the memory cell; and
applying a second voltage only to the second sub bit line when reading the memory cell, wherein
the first voltage is higher than the second voltage.

6. The method of claim 5, wherein
the first voltage is 5 V, and the second voltage is 1 V.
